(19) United States
(12) Patent Application Publication
(10) Pub. No.: US 2026/0322370 A1
(43) Pub. Date: Oct. 15, 2026

(54) Electric Power Source Switching Apparatus, Vehicle Control Apparatus, and Electric Power Source Switching Method

(71) Applicant: Hitachi Astemo, Ltd., Hitachinaka-shi, Ibaraki (JP)

(72) Inventors: Hiroshi NAKANO, Chiyoda-ku, Tokyo (JP); Nobuyasu KANEKAWA, Chiyoda-ku, Tokyo (JP); Takao FUKUDA, Hitachinaka-shi, Ibaraki (JP); Kentaro JUMONJI, Hitachinaka-shi, Ibaraki (JP)

(21) Appl. No.: 19/108,467

(22) PCT Filed: Jul. 31, 2023
(86) PCT No.: PCT/JP2023/028026

§ 371 Date: Mar. 4, 2025

(30) Foreign Application Priority Data
Sep. 26, 2022 (JP) 2022-152650

(51) Int. Cl. H03K 17/0812; B60L 58/10

(52) U.S. Cl. CPC H03K 17/08122; B60L 58/10; B60L 2270/20

(57) ABSTRACT

Provided is an electric power source switching apparatus that is able to suppress damage to a semiconductor switch even in a case where first and second power supply sources differ in output voltage. The electric power source switching apparatus (1) includes a first semiconductor switch (3a) connected to a first power supply source (2a), a second semiconductor switch (3b) connected to a second power supply source (2b), and a switch control apparatus (7) configured to control drive voltages (Vga, Vgb) of the first and second semiconductor switches. When switching from one of the first power supply source (2a) and the second power supply source (2b) to the other, the switch control apparatus (7) provides an intermediate state in which the semiconductor switch connected to the power supply source configured to supply electric power after switching is held in an unsaturated state, and changes a holding time of the intermediate state in accordance with a voltage difference between voltages (Va, Vb) outputted from the first and second power supply sources.

### TECHNICAL FIELD

The present invention relates to an electric power source switching apparatus, a vehicle control apparatus, and an electric power source switching method, and more particularly relates to a technology for protecting an electric power source switching circuit during electric power supply.

### BACKGROUND ART

In recent years, with the advancement of electric vehicles and autonomous driving in the field of automobiles, components such as conventional hydraulic and mechanical systems are increasingly being electrified. As a result, it is demanded that onboard power supply systems be improved to reduce the number of wire harnesses used for power supply and increase the reliability (redundancy) and efficiency of power supply systems. Conventionally, the onboard power supply systems controlled the power supply using mechanical switches such as relays and fuses. In recent years, however, power control systems using semiconductor switches have been widely used. The semiconductor switches have a faster switching speed than relays, and are able to avoid momentary interruption of power supply in the case of electric power source switching. Further, since the semiconductor switches do not have mechanical contacts, they are highly durable, and the limits on the number of switching times have been significantly relaxed.

Conventional technologies for power supply systems using the above-described semiconductor switches are disclosed in Patent Literature 1 and Patent Literature 2. Disclosed in Patent Literature 1 is a protection technology for inhibiting a reverse current flow from a second power supply to a first power supply without increasing the size and cost of a control circuit.

Meanwhile, disclosed in Patent Literature 2 is a configuration including a first switch pair for selectively connecting a first power supply node to an output node, a second switch pair for selectively connecting a second power supply node to the output node, and a switch control circuit. The switch control circuit operates to connect only one of the first and second power supply nodes to the output node at any point of time.

### CITATION LIST

### Patent Literature

Patent Literature 1: Japanese Unexamined Patent Application Publication No. 2002-061736
Patent Literature 2: Japanese Unexamined Patent Application Publication (Translation of PCT Application) No. 2019-514328

### SUMMARY OF INVENTION

### Technical Problem

When a main power supply drops, the technology described in Patent Literature 1 disconnects the main power supply to prevent a reverse current flow from a sub-power supply to the main power supply. This technology performs a switching operation only when the main power supply fails, and is unable to selectively supply electric power during normal use through the use of the main power supply and the sub-power supply.

The technology described in Patent Literature 2 is able to selectively connect first and second power supply sources to the output node. However, this technology is configured to connect only one of the first and second power supply sources to the output node. Therefore, a temporary power failure may occur at the time of electric power source switching. Further, if the first and second power supply sources differ in power supply voltage due, for instance, to individual differences or deterioration of the power supplies, an overcurrent may flow through a semiconductor switch due to an inrush current or discharge current at the time of switching, and thus damage the semiconductor switch.

Furthermore, since the inrush current at the time of switching varies depending on the current capacity of a connected load, it is generally necessary to estimate the maximum current under worst-case conditions in which all connected loads are operating, and to select a semiconductor switch that satisfies such conditions. This results in an increase in the cost of the semiconductor switch.

Under the above circumstances, there has been a demand for a method that is able to suppress damage to the semiconductor switch even in a case where the first and second power supply sources differ in output voltage.

### Solution to Problem

In order to solve the above problem, according to an aspect of the present invention, there is provided an electric power source switching apparatus including a first semiconductor switch, a second semiconductor switch, and a switch control apparatus. The first semiconductor switch is disposed between a load device and a first power supply source configured to supply electric power to the load device. The second semiconductor switch is disposed between the load device and a second power supply source configured to supply electric power to the load device. The switch control apparatus controls the drive voltages of the first and second semiconductor switches.

When switching from one of the first and second power supply sources to the other, the switch control apparatus provides an intermediate state in which the semiconductor switch connected to the power supply source configured to supply electric power after switching is held in an unsaturated state, and changes the holding time of the intermediate state in accordance with the voltage difference between voltages outputted from the first and second power supply sources.

### Advantageous Effects of Invention

At least, an aspect of the present invention is such that the holding time of the intermediate state of a semiconductor switch connected to the power supply source that supplies electric power after switching is changed in accordance with the voltage difference between the output voltages of the first power supply source and second power supply source. As a result, even if the first power supply source and the second power supply source differ in output voltage, it is possible to suppress damage that is caused to the semiconductor switch due to an overcurrent.

Objects, configurations, and effects other than the above will be apparent from the description of the following embodiments.

### BRIEF DESCRIPTION OF DRAWINGS

FIG. 1 is a schematic diagram illustrating an example in which a plurality of electric power sources are connected to a vehicle control apparatus mounted on a vehicle.

FIG. 2 is a diagram illustrating an example of the configuration of an electric power source switching apparatus according to a first embodiment of the present invention.

FIG. 3 is a diagram illustrating an example of the operation of an electric power source switching apparatus according to the first embodiment of the present invention.

FIG. 4 is a diagram illustrating an example of the configuration of an electric power source switching apparatus according to a second embodiment of the present invention.

FIG. 5 is an explanatory diagram illustrating how the electric power source switching apparatus according to the second embodiment of the present invention estimates an inrush current at the time of electric power source switching by using load information.

FIG. 6 is a diagram illustrating an example of the operation of an electric power source switching apparatus according to the second embodiment of the present invention.

FIG. 7 is a diagram illustrating an example of the configuration of an electric power source switching apparatus according to a third embodiment of the present invention.

FIG. 8 is a diagram illustrating an example of the configuration of an electric power source switching apparatus according to a fourth embodiment of the present invention.

FIG. 9 is a diagram illustrating an example of the operation of an electric power source switching apparatus according to the fourth embodiment of the present invention.

FIG. 10 is an explanatory diagram illustrating advantageous effects that are obtained when an overlap period is provided for the gate voltages of first and second semiconductor switches in the electric power source switching apparatus according to the fourth embodiment of the present invention.

FIG. 11 is a diagram illustrating an example of the configuration of an electric power source switching apparatus according to a fifth embodiment of the present invention.

FIG. 12 is a diagram illustrating a first example of the configuration for turning ON a semiconductor switch in the electric power source switching apparatus according to a sixth embodiment of the present invention.

FIG. 13 is a diagram illustrating an example of the operation of the semiconductor switch in the first example of the configuration of the electric power source switching apparatus according to the sixth embodiment of the present invention.

FIG. 14 is a diagram illustrating a second example of the configuration for turning ON a semiconductor switch in the electric power source switching apparatus according to the sixth embodiment of the present invention.

FIG. 15 is a diagram illustrating an example of the operation of the semiconductor switch in the second example of the configuration of the electric power source switching apparatus according to the sixth embodiment of the present invention.

FIG. 16 is a diagram illustrating a third example of the configuration for turning ON a semiconductor switch in the electric power source switching apparatus according to the sixth embodiment of the present invention.

FIG. 17 is a diagram illustrating an example of the operation of the semiconductor switch in the third example of the configuration of the electric power source switching apparatus according to the sixth embodiment of the present invention.

FIG. 18 is a block diagram illustrating an example of the hardware configuration of a computer included in the electric power source switching apparatus according to each embodiment of the present invention.

### DESCRIPTION OF EMBODIMENTS

Examples of modes for implementing the present invention (hereinafter referred to as the “embodiments”) will now be described with reference to the accompanying drawings. In this document and the accompanying drawings, component elements identical with each other or having substantially the same functions are designated by the same reference signs and will not be redundantly described. Further, in a case where there are a plurality of component elements having the same or similar functions, different subscripts may be appended to the same reference signs for the purpose of explanation. Furthermore, when there is no need to distinguish between such plurality of component elements, the subscripts may be omitted from the description.

### First Embodiment

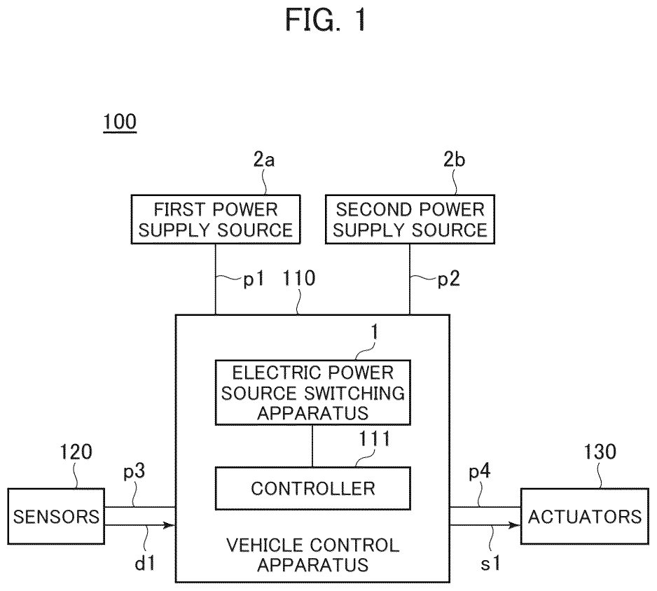

First of all, an example of a vehicle equipped with an electric power source switching apparatus configured to switch between a plurality of electric power sources will be described with reference to FIG. 1.

FIG. 1 is a schematic diagram illustrating an example in which a plurality of electric power sources are connected to a vehicle control apparatus mounted on a vehicle. As depicted in FIG. 1, the vehicle 100 includes a vehicle control apparatus 110, sensors 120, actuators 130, a first power supply source (“first power supply” in FIG. 1) 2a, and a second power supply source (“second power supply” in FIG. 1) 2b. The vehicle control apparatus 110 is connected to the sensors 120, the actuators 130, the first power supply source 2a, and the second power supply source 2b.

The vehicle control apparatus 110 includes an electric power source switching apparatus 1 and a controller 111. The controller 111 receives detection signals from the sensors 120 via a signal line d1, and controls the vehicle 100 by transmitting control signals to the actuators 130 via a control line s1. The controller 111 analyzes the detection signals received from the sensors 120, and generates control signals in accordance with the result of analysis in order to control the operations of the actuators 130. The controller 111 may be formed, for example, by using an ECU (Electronic Control Unit). The sensors 120 and the actuators 130 are load devices that consume electric power supplied from the first power supply source 2a or the second power supply source 2b.

The electric power source switching apparatus 1 switches a power supply source between the first power supply source 2a and the second power supply source 2b in accordance with the power supply voltages of the first power supply source 2a and second power supply source 2b. The electric power source switching apparatus 1 receives electric power supplied from the first power supply source 2a via a power supply line p1, and receives electric power supplied from the second power supply source 2b via a power supply line p2. The electric power source switching apparatus 1 supplies the electric power received from the first power supply source 2a or the second power supply source 2b to the sensors 120 via a power supply line p3 and to the actuators 130 via a power supply line p4.

The configuration described in the example depicted in FIG. 1 is such that the electric power source switching apparatus 1 is built in the vehicle control apparatus 110. Alternatively, however, the electric power source switching apparatus 1 may be separate from the vehicle control apparatus 110. Further, an alternative configuration may be employed so as to allow the controller 111 to control the electric power source switching apparatus 1. For example, a terminal used, for instance, by a mechanic may be connected to the controller 111 so that the controller 111 is able to control ON/OFF of a first semiconductor switch 3a and second semiconductor switch 3b in accordance with commands from the terminal.

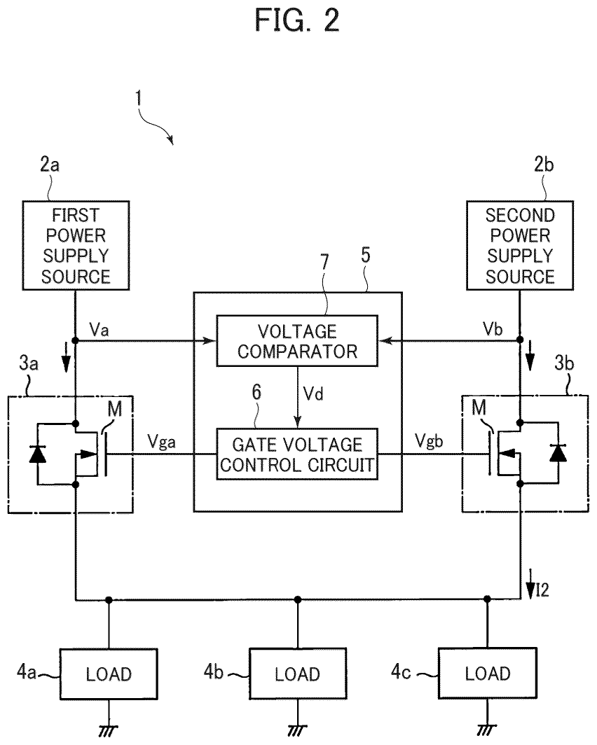

Next, a configuration of the electric power source switching apparatus 1 according to the first embodiment of the present invention will be described with reference to FIG. 2.

FIG. 2 is a diagram illustrating an example of the configuration of the electric power source switching apparatus 1 according to a first embodiment of the present invention. The electric power source switching apparatus 1 is connected to the first power supply source 2a and the second power supply source 2b. For example, the first power supply source 2a and the second power supply source 2b are connected to an onboard battery and a power converter such as a DC/DC converter. The electric power source switching apparatus 1 includes the first semiconductor switch 3a, the first semiconductor switch 3b and a switch control apparatus 5.

The first semiconductor switch 3a is disposed between load devices 4a to 4c and the first power supply source 2a, which supplies electric power to the load devices 4a to 4c. The electric power from the first power supply source 2a is supplied to a plurality of load devices 4a to 4c through the first semiconductor switch 3a. For example, the first semiconductor switch 3a includes a field-effect transistor M. The field-effect transistor M included in the first semiconductor switch 3a is configured such that a body diode (referred to also as a “parasitic diode”) formed between the drain and source of first semiconductor switch 3a is connected in a direction opposite to the direction of power supply from the first power supply source 2a. That is to say, the anode of the body diode is connected to the source of the field-effect transistor M, and the cathode is connected to the drain of the field-effect transistor M.

The second semiconductor switch 3b is disposed between the load devices 4a to 4c and the second power supply source 2b, which supplies electric power to the load devices 4a to 4c. The electric power from the second power supply source 2b is supplied to a plurality of load devices 4a to 4c through the second semiconductor switch 3b. For example, the second semiconductor switch 3b includes the field-effect transistor M. The field-effect transistor M included in the second semiconductor switch 3b is configured such that a body diode formed between the drain and source of second semiconductor switch 3b is connected in a direction opposite to the direction of power supply from the second power supply source 2b. That is to say, the anode of the body diode is connected to the source of the field-effect transistor M, and the cathode is connected to the drain of the field-effect transistor M.

The load devices 4a to 4c are configured such that electric power can be supplied from either the first power supply source 2a or the second power supply source 2b in accordance with control of the first semiconductor switch 3a and second semiconductor switch 3b. An output terminal of the first semiconductor switch 3a and an output terminal of the second semiconductor switch 3b are electrically connected, and the plurality of load devices 4a to 4c are connected to the output terminals.

The load devices 4a to 4c are actuators 130, such as electric motors and solenoids mounted on the vehicle 100, or sensors 120, such as cameras. Further, in the present embodiment, it is assumed that the number of connected load devices is three. However, the number of connected load devices is not limited to three. An alternative configuration may be employed so that two or more load devices are connected. In the following description, when there is no need to distinguish between the load devices 4a to 4c, they will be referred to as the “load devices 4.”

The switch control apparatus 5 outputs control signals (gate voltages) to the first semiconductor switch 3a and the second semiconductor switch 3b in order to switch the power supply. The switch control apparatus 5 includes a voltage comparator 7 and a gate voltage control circuit 6.

The voltage comparator 7 monitors a voltage Va outputted from the first power supply source 2a and a voltage Vb outputted from the second power supply source 2b, and detects a voltage difference Vd (=Va−Vb). The voltage difference Vd is outputted to the gate voltage control circuit 6.

In accordance with the voltage difference Vd, the gate voltage control circuit 6 generates and outputs a gate voltage Vga of the field-effect transistor M used as the first semiconductor switch 3a, and a gate voltage Vgb of the field-effect transistor M used as the second semiconductor switch 3b. When the gate voltage Vga of the first semiconductor switch 3a goes High, the first semiconductor switch 3a turns ON.

When the gate voltage Vgb of the second semiconductor switch 3b goes High, the second semiconductor switch 3b turns ON. In the following description, when there is no need to distinguish between the first semiconductor switch 3a and the second semiconductor switch 3b, they will be referred to as the “semiconductor switches 3.”

In FIG. 2, an N-channel MOS field-effect transistor is used as the field-effect transistor M. However, a P-channel MOS field-effect transistor or other field-effect transistor may alternatively be used. Alternatively, the semiconductor switches 3 may be configured using a bipolar transistor.

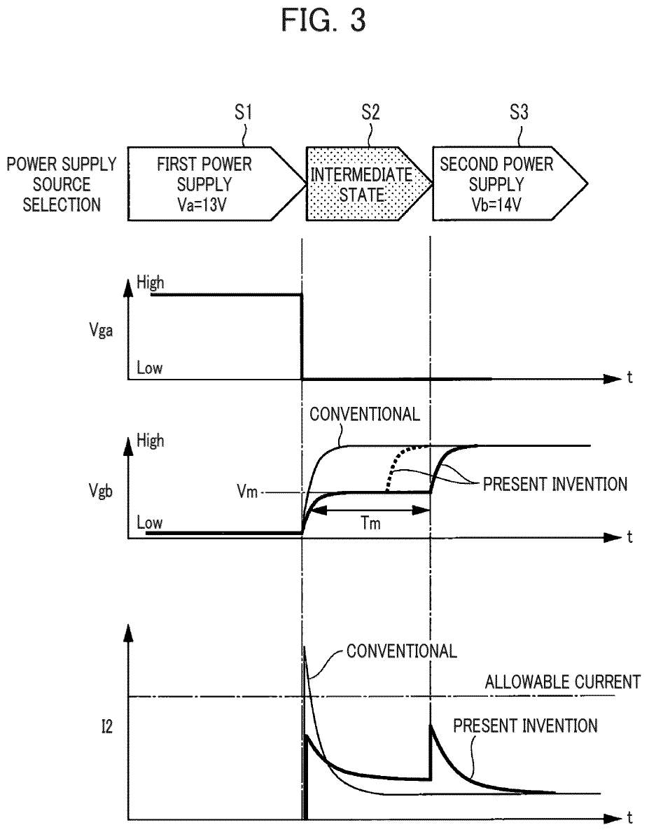

An example of the operation of the electric power source switching apparatus 1 according to the present embodiment will now be described with reference to FIG. 3. FIG. 3 is a diagram illustrating an example of the operation of the electric power source switching apparatus 1. The upper part of FIG. 3 depicts a voltage profile of the gate voltage Vga at the time of switching from the first power supply source 2a to the second power supply source 2b, the middle part of FIG. 3 depicts a voltage profile of the gate voltage Vgb, and the lower part of FIG. 3 depicts a current I2 flowing through the second semiconductor switch 3b. In FIG. 3, a horizontal axis represents time t.

The voltages Va, Vb outputted from the first power supply source 2a and the second power supply source 2b vary due, for instance, to the individual difference of the onboard battery and DC/DC converter, the state of charge, the length of wiring, and the deterioration of the onboard battery and power wiring. The following describes an example in which the power supply source is switched from the first power supply source 2a generating a low output voltage to the second power supply source 2b generating a high output voltage on the assumption that the voltage Va of the first power supply source 2a is 13 V and the voltage Vb of the second power supply source 2b is 14 V.

As depicted in FIG. 3, when electric power is supplied from the first power supply source 2a to the load devices 4a to 4c (first power supply S1), the gate voltage Vga of the first semiconductor switch 3a is a High level, and the gate voltage Vga of the second semiconductor switch 3b is at a Low level.

When the power supply source is to be switched to the second power supply source 2b from the state of first power supply S1, the gate voltage control circuit 6 first sets the gate voltage Vga of the first semiconductor switch 3a to the Low level. Then, simultaneously with this voltage setting, or after the gate voltage Vgb of the second semiconductor switch 3b starts rising, the gate voltage control circuit 6 raises the gate voltage Vgb to an intermediate voltage Vm between the Low level and the High level, and holds the intermediate voltage Vm for a holding time Tm (intermediate state S2).

It should be noted that a certain amount of time (rise time) is required for the gate voltage control circuit 6 to increase the gate voltage from the Low level to the intermediate voltage Vm. Therefore, it can be said that the time during which the gate voltage is actually held at the intermediate voltage Vm is shorter than the holding time Tm beginning from the moment at which the gate voltage rise depicted in FIG. 3 starts. However, since the rise time is shorter than the time during which the gate voltage is held at a constant value of the intermediate voltage Vm, the holding time Tm is regarded as the period between the start of gate voltage rise and the start of voltage rise to the next voltage level. For example, the next voltage level is High in FIG. 3, and is a second-stage intermediate voltage in FIG. 13, which will be described later.

Subsequently, the gate voltage control circuit 6 raises the gate voltage Vgb of the second semiconductor switch 3b to the High level. As a result, the power supply source is completely switched from the first power supply source 2a to the second power supply source 2b (second power supply S3).

As described above, in the present embodiment, the voltage levels of the gate voltages Vga, Vgb are in three different states, namely, the High level, the Low level, and the intermediate voltage. The high level represents a voltage at which the on-resistance of the field-effect transistors serving as the first semiconductor switch 3a and the second semiconductor switch 3b is minimized, for example, a voltage at which the gate-source voltage is 10 V or higher. The low level represents a voltage at which the output characteristics (I_{D}-V_{DS} characteristics) of a field-effect transistor are in a blocked region, for example, a voltage at which the gate-source voltage is 0 V. The intermediate voltage is a voltage at which the output characteristics of a field-effect transistor are in an unsaturated region, and is a voltage at which the source-drain resistance varies with the gate voltage.

The holding time Tm is dynamically set in accordance with the voltage difference Vd between the voltages outputted from the first power supply source 2a and the second power supply source 2b. When the voltage difference Vd is small, the holding time Tm is shortened, and when the voltage difference Vd is great, the holding time Tm is lengthened. That is to say, when the voltage difference Vd is greater than a predetermined value, the gate voltage control circuit 6 changes the holding time Tm to be longer than a preset reference time, and when the voltage difference Vd is equal to or smaller than the predetermined value, the gate voltage control circuit 6 changes the holding time Tm to be shorter than the preset reference time.

In the present embodiment, a state in which the gate voltage of the semiconductor switch is between the Low level and the High level is defined as the “intermediate state.” In conventional electric power source switching apparatuses, the voltage profile remains unchanged until the gate voltage Vgb rises from the Low level to the High level in the intermediate state, as indicated by the thin solid line in the middle part of FIG. 3. The holding time is the time for limiting an inrush current that flows through the semiconductor switch at the time of electric power source switching, and can also be called a “current limit time.”

When switching is performed between power supply sources having different voltage values, for example, when the power supply source is switched from the first power supply source 2a (voltage Va=13 V) to the second power supply source 2b (voltage Vb=14 V) as described in conjunction with the present embodiment, the inrush current occurs in accordance with the voltage difference Vd between the two power supply sources. In conventional configurations, a large inrush current exceeding an allowable current indicated by the dash-dotted line flows through the second semiconductor switch 3b.

The following describes the current I2, which flows through the second semiconductor switch 3b when switching is performed from the intermediate state S2 to the second power supply S3 in the configuration according to the present embodiment. As depicted in the lower part of FIG. 3, a first peak current flows when the gate voltage Vgb of the second semiconductor switch 3b rises to the intermediate voltage Vm, and then, after the first peak current decreases, a second peak current flows when the gate voltage Vgb rises to the High level.

As described above, the present embodiment is configured such that the gate voltage Vgb of the second semiconductor switch 3b is raised stepwise without being abruptly raised from the Low level to the High level. Therefore, a peak current can be dispersed so that the current I2 (peak current) flowing through the second semiconductor switch 3b at the time of electric power source switching does not exceed the allowable current. Further, the present embodiment is configured such that the power supply source can be changed in accordance with the voltage difference Vd between the output voltages of the first power supply source 2a and the second power supply source 2b. Therefore, switching can be performed from one power supply source to another without exceeding the allowable current. Conventionally, there has been no configuration for changing the holding time Tm of the intermediate voltage Vm in the intermediate state at the time of electric power source switching in accordance with the voltage difference Vd. Therefore, conventionally, when the voltage difference Vd increases, the peak current of a semiconductor switch increases accordingly and may exceed the allowable current. However, this problem is solved by the present embodiment.

As described above, the electric power source switching apparatus (electric power source switching apparatus 1) according to the first embodiment includes a first semiconductor switch (first semiconductor switch 3a), a second semiconductor switch (second semiconductor switch 3b), and a switch control apparatus (switch control apparatus 5). The first semiconductor switch (first semiconductor switch 3a) is disposed between the load devices (4a to 4c) and a first power supply source (first power supply source 2a) configured to supply electric power to the load devices (4a to 4c). The second semiconductor switch (second semiconductor switch 3b) is disposed between the load devices and a second power supply source (second power supply source 2b) configured to supply electric power to the load devices. The switch control apparatus (switch control apparatus 5) controls the drive voltages of the first semiconductor switch and second semiconductor switch.

When switching from one of the first and second power supply sources to the other, the switch control apparatus provides an intermediate state in which the semiconductor switch (the second semiconductor switch 3b) connected to the power supply source (for example, the second power supply source 2b) configured to supply electric power after switching is held in an unsaturated state, and changes the holding time (holding time Tm) of the intermediate state in accordance with the voltage difference (voltage difference Vd) between voltages outputted from the first and second power supply sources.

The above-described configuration of the present embodiment is such that the holding time (current limiting time) of the intermediate state of a semiconductor switch connected to the power supply source that supplies electric power after switching is changed in accordance with the voltage difference between the output voltages of the first power supply source and second power supply source. As a result, even if the first power supply source and the second power supply source differ in output voltage, it is possible to suppress damage that is caused to the semiconductor switch due to an overcurrent, and smoothly change the power supply source without interrupting the power supply.

### Second Embodiment

Next, the electric power source switching apparatus according to a second embodiment will be described. The second embodiment is an example of a configuration in which the first semiconductor switch 3a and the second semiconductor switch 3b are controlled in consideration of the voltage difference Vd between the output voltages of the first power supply source 2a and second power supply source 2b as well as information regarding the load devices 4 (load information). The following description of the electric power source switching apparatus according to the second embodiment will focus on the differences from the first embodiment.

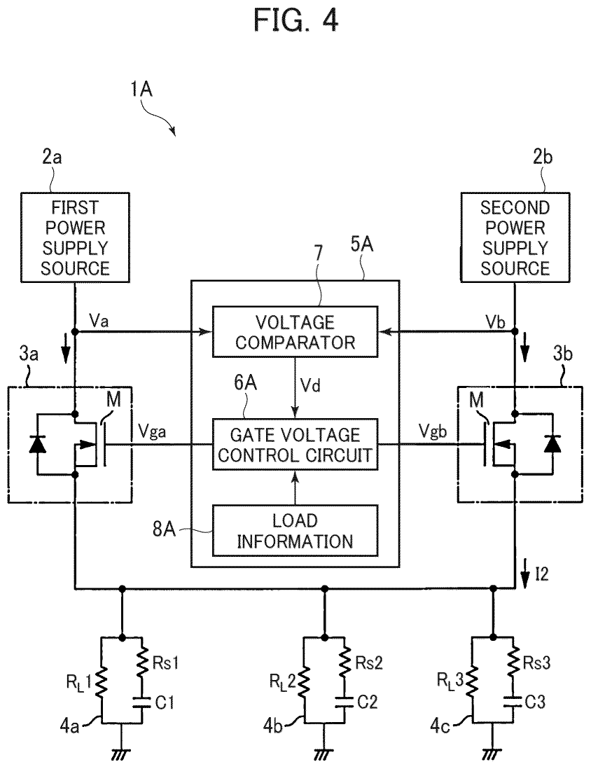

First of all, the configuration of the electric power source switching apparatus according to the present embodiment will be described with reference to FIG. 4.

FIG. 4 is a diagram illustrating an example of the configuration of an electric power source switching apparatus 1A according to the present embodiment. The electric power source switching apparatus 1A includes a switch control apparatus 5A instead of the switch control apparatus 5 of the electric power source switching apparatus 1 according to the first embodiment. More specifically, the electric power source switching apparatus 1A includes the first semiconductor switch 3a, the second semiconductor switch 3b, and the switch control apparatus 5A.

The switch control apparatus 5A outputs control signals to the first semiconductor switch 3a and the second semiconductor switch 3b in order to switch the power supply.

The switch control apparatus 5A includes the voltage comparator 7, a gate voltage control circuit 6A and load information 8A.

The gate voltage control circuit 6A generates and outputs the gate voltage Vga of the first semiconductor switch 3a (field-effect transistor M) and the gate voltage Vgb of the second semiconductor switch 3b (field-effect transistor M) in accordance with the voltage difference Vd outputted from the voltage comparator 7. Further, the gate voltage control circuit 6A generates and outputs the gate voltages Vga, Vgb in accordance with the load information 8A based on the equivalent electrical resistance and equivalent capacitance of the load devices 4a to 4c. The load information 8A is stored, for example, in a memory. The gate voltage control circuit 6A references the memory in which the load information 8A is stored, and generates the gate voltages Vga, Vgb.

The present embodiment is characterized in that the gate voltages Vga, Vgb are generated and outputted in accordance with the load information 8A in addition to the voltage difference Vd. The load information 8A is a parameter based on an equivalent circuit model of the load devices 4a to 4c as depicted in FIG. 4. The load devices 4a to 4c can be represented by an equivalent circuit with the equivalent electrical resistance and equivalent capacitance depicted in FIG. 4. The load information 8A is based on the equivalent electrical resistance and equivalent capacitance of the plurality of load devices 4a to 4c. In the present embodiment, it is desirable that the information representing the electrical characteristics of the load devices include at least the equivalent electrical resistance and the equivalent capacitance. For example, although the electrical resistance and capacitance of the load devices 4 are exemplified as the electrical characteristics, a reactance component may be additionally taken into consideration.

For example, the load device 4a is represented as an equivalent circuit in which an equivalent electrical resistance R_{L}1 is connected in parallel with an equivalent capacitance C1 and an equivalent electrical resistance R_{S}1, which are connected in series. Similarly, the load device 4b is represented as an equivalent circuit in which an equivalent electrical resistance R_{L}2 is connected in parallel with an equivalent capacitance C2 and an equivalent electrical resistance R_{S}2, which are connected in series. Additionally, the load device 4c is represented as an equivalent circuit in which an equivalent electrical resistance R_{L}3 is connected in parallel with an equivalent capacitance C3 and an equivalent electrical resistance R_{S}3, which are connected in series. The equivalent circuits of the load devices 4a to 4c are connected at one end to a power supply line and at the other end to ground.

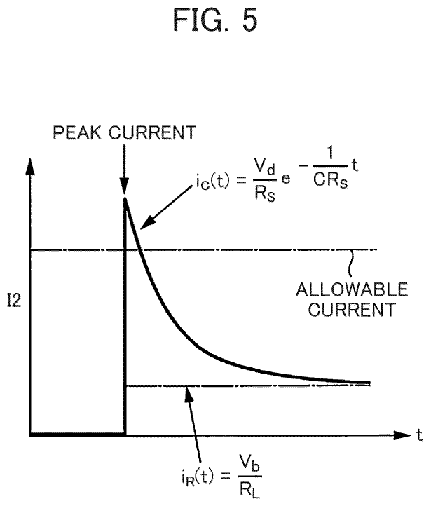

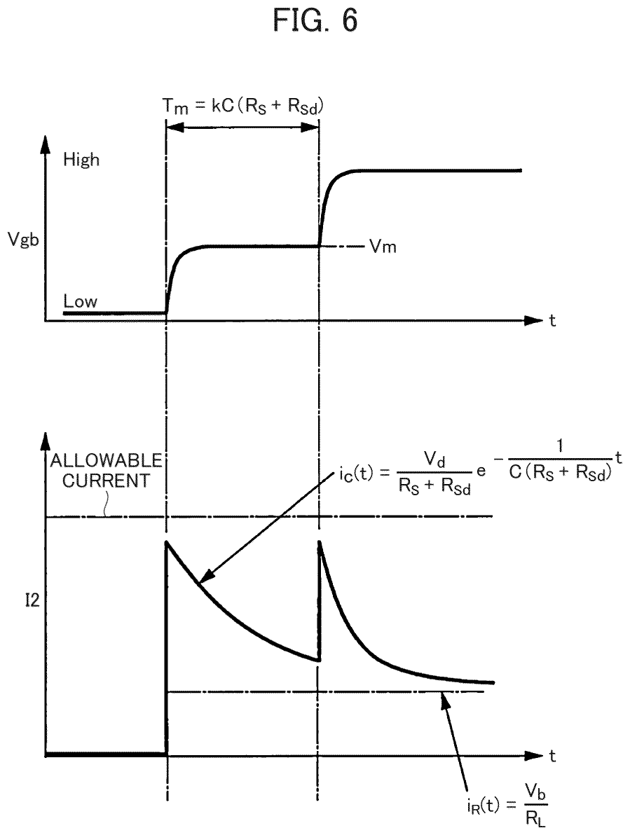

An example of the procedure for determining, in the present embodiment, a gate voltage profile in accordance with the above-described load information 8A will now be described with reference to FIGS. 5 and 6.

FIG. 5 is an explanatory diagram illustrating how the electric power source switching apparatus 1A estimates the inrush current at the time of electric power source switching by using the load information 8A. In FIG. 5, the vertical axis represents the current I2 flowing through the second semiconductor switch 3b, and the horizontal axis represents time t. For example, in a case where switching from the first power supply source 2a to the second power supply source 2b is performed, the current I2 flowing through the second semiconductor switch 3b can be predicted by Equation (1) below.

$$[ Equation . 1 ]$$

$$I 2 ( t ) = {i}_{c} + {i}_{R} = \frac{{V}_{d}}{{R}_{s}} {e}^{- \frac{1}{{CR}_{s}} t} + \frac{{V}_{b}}{{R}_{L}} \qquad ( 1 )$$

Here, “i_{C}” is the capacitance charging current of the current I2 flowing through the second semiconductor switch 3b. “i_{R}” is the DC component of the current I2 flowing through the second semiconductor switch 3b. “t” is the time elapsed since the gate voltage Vgb was applied to the second semiconductor switch 3b. “Vd” is the voltage difference between the voltages outputted from the first power supply source 2a and the second power supply source 2b (hereinafter referred to also as the “power supply voltage difference”). “Rs” is the parallel combined resistance of the electrical resistances (Rs1 to Rs3 in FIG. 4) connected in series with the equivalent capacitance of each load device 4. “C” is the parallel combined capacitance of the equivalent capacitances (C1 to C3) of each load device 4. “Vb” is the output voltage of the second power supply source 2b. “R_{L}” is the parallel combined resistance of the equivalent electrical resistance (R_{L}1 to R_{L}3) of each load device 4.

Based on Equation (1) above, the peak current of the inrush current flowing through the second semiconductor switch 3b at the time of electric power source switching is estimated. In a case where the peak current exceeds the allowable current, Equation (2) below is used in consideration of the source-drain resistance Rsd of the second semiconductor switch 3b in order to calculate the value of the source-drain resistance Rsd without exceeding the allowable current.

$$[ Equation . 2 ]$$

$$I 2 ( t ) = {i}_{c} + {i}_{R} = \frac{{V}_{d}}{{R}_{s} + {R}_{sd}} {e}^{- \frac{1}{C ( {R}_{s} + {R}_{sd} )} t} + \frac{{V}_{b}}{{R}_{L}} \qquad ( 2 )$$

After the source-drain resistance Rsd is calculated from Equation (2), the gate voltage Vgb at which the source-drain resistance is equal to Rsd is determined based on the electrical characteristics of the field-effect transistor M included in the second semiconductor switch 3b. The gate voltage Vgb can be calculated using, for example, the drain current-gate-source voltage characteristics (Id-V_{GS} characteristics). The value of the gate voltage Vgb determined here is the intermediate voltage value in the intermediate state in the present invention (intermediate voltage Vm in FIG. 6).

Next, an example of the operation of an electric power source switching apparatus 1B according to the present embodiment will be described with reference to FIG. 6.

FIG. 6 is a diagram illustrating an example of the operation of the electric power source switching apparatus 1B. The upper part of FIG. 6 depicts the voltage profile of the gate voltage Vgb generated by the gate voltage control circuit 6, and the lower part of FIG. 6 depicts the current I2 of the second semiconductor switch 3b. In FIG. 5, the horizontal axis represents time t.

First of all, after electric power source switching, the gate voltage control circuit 6 raises the gate voltage Vgb from a Low level to the intermediate voltage Vm, which is determined as described above. The holding time Tm at the intermediate voltage Vm is determined by Equation (3) below in accordance with the equivalent electrical resistance Rs and equivalent capacitance C of the load devices 4 and with the source-drain resistance Rsd of the field-effect transistor.

$$[ Equation . 3 ]$$

$$Tm = k C ( {R}_{s} + {R}_{sd} ) \qquad ( 3 )$$

In Equation (3), “k” is a constant. When the gate voltage Vgb is raised to the High level after the gate voltage Vgb is held in the intermediate state for a period of the holding time Tm, the second semiconductor switch 3b is turned completely on. The current I2 in this voltage profile, the first peak current flows when the gate voltage Vgb is changed to the intermediate voltage Vm, and the second peak current flows when the gate voltage Vgb subsequently rises to the High level. The present embodiment is configured such that the peak current is dispersed into the first peak current and the second peak current in accordance with the voltage difference Vd and with the electrical characteristics of the load devices 4. Therefore, the peak current can be changed without exceeding the allowable current.

In the above-described example of the present embodiment, the holding time Tm is determined from the equivalent electrical resistance and the equivalent capacitance in the manner described above. However, the holding time Tm can be optimized by multiplying the time constant (=C (Rs+Rsd)) in Equation (3) by a predetermined coefficient k. That is to say, the rising curve (rising speed) of the gate voltage Vgd can be varied by the value of k as needed to change the holding time Tm. For example, if the second peak current value of the current I2 has a margin for the allowable current, k<1 may be set so that the holding time Tm is shorter than the time constant, and if the second peak current value of the current I2 has no margin for the allowable current, k>1 may be set so that the holding time Tm is longer than the time constant. Stated differently, the gate voltage Vgb can be optimized by using the holding time Tm and the source-drain resistance Rsd of the field-effect transistor M of the second semiconductor switch 3b as parameters.

Further, in the above-described example of the present embodiment, the gate voltage Vgb (intermediate voltage Vm) held in the intermediate state has one value. Alternatively, however, a plurality of voltage values may be set to raise the gate voltage Vgb in two or more steps. These voltage profiles are design parameters and are set appropriately in accordance, for example, with the load devices 4 and with the characteristics of the semiconductor switches 3.

As described above, the switch control apparatus (switch control apparatus 5A) in the second embodiment is configured to change the holding time Tm of the intermediate state in accordance with the voltage difference Vd between the voltages outputted from the first power supply source 2a and the second power supply source 2b and with the information (load information 8A) representing the electrical characteristics of the load devices 4a to 4c.

The above-described configuration of the present embodiment is such that the gate voltage control circuit 6 sets the voltage profile of the gate voltage of the semiconductor switches 3 in accordance with the information regarding the load devices 4 (load information 8A) in addition to the voltage difference Vd. Even if the inrush current at the time of electric power source switching changes due to the addition or update of a load device 4, the above-described configuration makes it possible to suppress the failure and deterioration of the semiconductor switches 3, which may occur due to the inrush current when the load information is changed. Stated differently, it is possible to cope with changes in the load devices 4 without replacing the semiconductor switches 3. For example, even if the number of connected loads or the current capacity is changed due to a later addition, such changes can be handled by software modification without having to replace the semiconductor switches 3.

In the foregoing description of the present embodiment, the equivalent electrical resistance and equivalent capacitance of the load devices 4 are indicated as the load information 8A. However, the load information 8A is not limited to such equivalent electrical resistance and equivalent capacitance. For example, the intermediate voltage Vm and the holding time Tm may be predetermined from the characteristics of the inrush current flowing through the semiconductor switches 3 and stored in a memory as the load information 8A. That is to say, the advantageous effects of the present invention can be obtained as long as the load information 8A is information that makes it possible to appropriately change the parameters (Tm, Vm) determining the voltage profile of the gate voltage depending on the electrical characteristics of the connected load devices 4, and change the voltage profile of the gate voltage and the holding time of the intermediate state.

### Third Embodiment

Next, the electric power source switching apparatus according to a third embodiment will be described. The third embodiment is an example in which the gate voltage of the semiconductor switches 3 is controlled in accordance with the information representing the electrical characteristics of an energized one of the load devices 4.

The configuration of the electric power source switching apparatus according to the present embodiment will be described with reference to FIG. 7.

FIG. 7 is a diagram illustrating an example of the configuration of the electric power source switching apparatus 1B according to the present embodiment. The electric power source switching apparatus 1B is basically configured based on the configuration of the electric power source switching apparatus 1A according to the second embodiment, and the following description of the electric power source switching apparatus 1B will focus on the differences from the second embodiment.

The electric power source switching apparatus 1B includes a switch control apparatus 5B instead of the switch control apparatus 5A of the electric power source switching apparatus 1 according to the second embodiment. That is to say, the electric power source switching apparatus 1B includes the first semiconductor switch 3a, the second semiconductor switch 3b, and the switch control apparatus 5B. The switch control apparatus 5B includes the voltage comparator 7, a gate voltage control circuit 6B and the load information 8A.

In addition to the component elements included in the second embodiment, the present embodiment includes load switches 9a to 9c and a load switch control apparatus 10. The load switches 9a to 9c are disposed on the power supply lines of the load devices 4a to 4c. The load switch control apparatus 10 controls the energization/de-energization of the load switches 9a to 9c in accordance with external commands. The load switch control apparatus 10 may be built in the controller 111 of the vehicle control apparatus 110 depicted in FIG. 1. The external commands specify whether or not to drive the connected load devices 4a to 4c on a respective basis.

The switch control apparatus 5B receives a load switch change command that is inputted from an electronic control unit (ECU) of a power management system. When, for example, failures (or signs of failure) are detected in the load devices 4, the load switches 9a to 9c are switched to stop the use of the load devices 4 or restrict their functions.

As the load switches, semiconductor switches including a field-effect transistor or mechanical switches, such as relays, can be used. The power supply to the load devices 4a to 4c is controlled by the load switches 9a to 9c. In the following description, when there is no need to distinguish between the load switches 9a to 9c, they will be referred to as the “load switches 9.”

The load information 8A is based on the equivalent electrical resistance and equivalent capacitance of the load devices 4a to 4c. However, the load information 8A in the present embodiment is updated in accordance with switching information regarding the load switches 9a to 9c (“switch information” in FIG. 7), which is transmitted from the load switch control apparatus 10, namely, the information regarding the load devices 4a to 4c energized, that is, connected to the power supply line.

Alternatively, the load information 8A may include information representing the electrical characteristics of all the load devices 4a to 4c, and based on the switch information, the load information 8A may be updated in accordance with the electrical characteristics of a driven load device 4 (the electrical characteristics of the equivalent circuit model) and stored in a memory.

The gate voltage control circuit 6B has the same function as the gate voltage control circuit 6A in the second embodiment. The gate voltage control circuit 6B references the memory in which the load information 8A is stored, and generates the gate voltages Vga, Vgb in the same manner as in the second embodiment.

Further, in a case where information representing the electrical characteristics of the load devices 4a to 4c is registered in the load information 8A, the gate voltage control circuit 6B may extract only information regarding the electrical characteristics of an energized load device 4 from the load information 8A in accordance with the switch information, and generate a gate voltage based on the extracted information regarding the electrical characteristics of the energized load device 4. The gate voltage control circuit 6B is able to acquire the switch information before electric power source switching by periodically communicating with the load switch control apparatus 10. For example, in FIG. 7, only the load switch 9a is energized, and the load device 4a is connected to the power supply line and driven. The gate voltage control circuit 6B generates a gate voltage in accordance with the load information 8A based on the electrical characteristics of the load device 4a.

The inrush current flowing through the semiconductor switches 3 at the time of electric power source switching is determined by a currently driven load device 4. Therefore, the present embodiment makes it possible to more accurately estimate the inrush current flowing through the semiconductor switches 3 at the time of electric power source switching, and generate an optimal gate voltage.

Furthermore, before switching from one power supply source to the other, the switch control apparatus 5B is able to stop the power supply to one of the load devices 4a to 4c and change the holding time Tm of the intermediate state in accordance with information representing the electrical characteristics (e.g., equivalent electrical resistance and equivalent capacitance) of an energized one of the load devices 4. For example, a plurality of load devices 4 may be classified beforehand into critical devices and non-critical devices, and the non-critical devices may be stopped at the time of electric power source switching. This makes it possible to decrease the number of load devices 4 connected at the time of electric power source switching, and reduce the inrush current flowing through the semiconductor switches 3 at the time of electric power source switching. For example, the critical devices are brake lights, headlights, windshield wipers, and other load devices important for safe driving of automobiles. Non-critical devices are audio devices, air conditioners, power windows, and other load devices that do not adversely affect the safe driving of automobiles even if they are temporarily stopped.

After electric power source switching, the load switch control apparatus 10 supplies electric power to the load devices 4 for which power supply has been stopped. In the above instance, the load switch control apparatus 10 energizes load switches 9 connected to the load devices 4, for which power supply has been stopped, without exceeding the allowable current of the semiconductor switches 3, and thus drives the load devices 4. For example, the load switch control apparatus 10 sequentially drives a plurality of stopped load devices 4 instead of simultaneously driving them. Alternatively, the load switch control apparatus 10 may prevent load devices 4 with large inrush currents (equivalent capacitances) from being simultaneously activated in order to prevent the allowable current of the semiconductor switches 3 from being exceeded. Conversely, as long as the allowable current of the semiconductor switches 3 is not exceeded, the power supply to a plurality of load devices 4 may be started simultaneously.

As described above, the switch control apparatus (switch control apparatus 5B) in the third embodiment is configured to change the holding time Tm of the intermediate state in accordance with information (load information 8A) representing the electrical characteristics of an energized one of the plurality of the load devices 4a to 4c.

The above-described configuration of the present embodiment is such that the holding time of the intermediate state of a semiconductor switch connected to the power supply source that supplies electric power after switching is changed in accordance with the voltage difference between the output voltages of the first power supply source and second power supply source, and the connected load device. As a result, even in a case where the difference in output voltage between the first and second power supply sources is varied, it is possible to inhibit the semiconductor switches from being damaged by an overcurrent, and smoothly switch the power supply source without interrupting the power supply. Additionally, since there is no need to create a design under the worst-case conditions of the current capacity of a load device connected to the electric power source switching apparatus, it is possible to reduce the cost of the semiconductor switches.

### Fourth Embodiment

Next, the electric power source switching apparatus according to a fourth embodiment will be described. The fourth embodiment is an example that is configured to prevent a reverse current from flowing from the load devices 4 to the first power supply source 2a and the second power supply source 2b, and prevent a through-current from flowing between the first power supply source 2a and the second power supply source 2b.

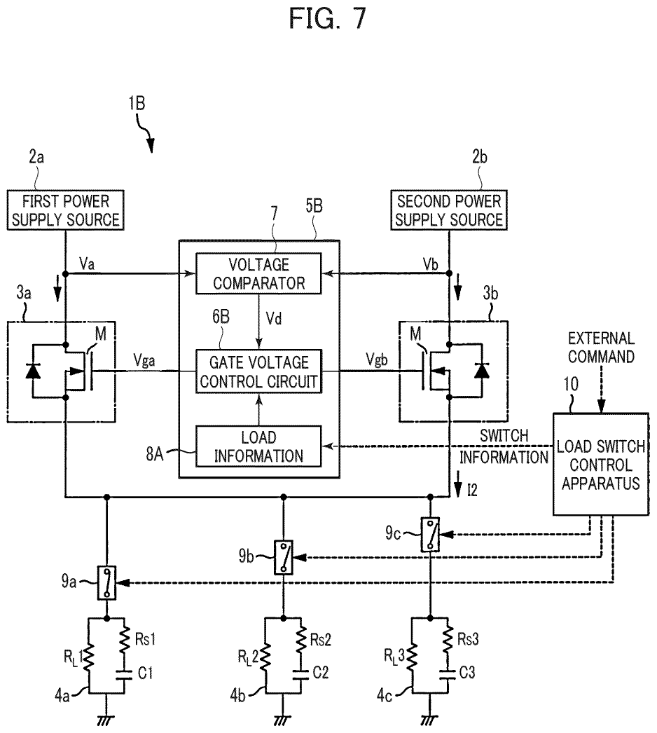

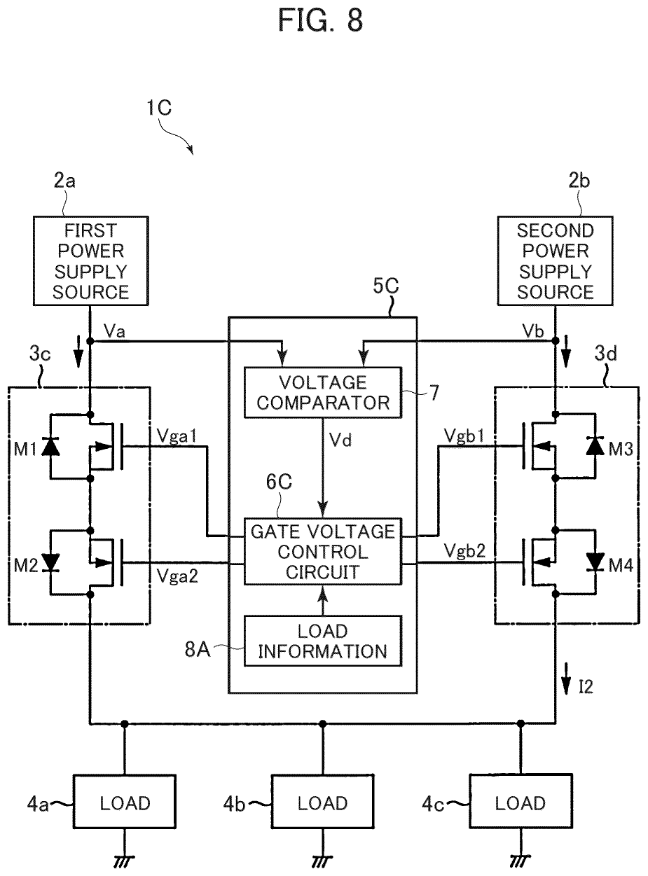

First of all, the configuration of the electric power source switching apparatus according to the present embodiment will be described with reference to FIG. 8.

FIG. 8 is a diagram illustrating an example of the configuration of an electric power source switching apparatus 1C according to the present embodiment. The electric power source switching apparatus 1C is basically configured based on the configuration of the electric power source switching apparatus 1A according to the second embodiment, and the following description of the electric power source switching apparatus 1C will focus on the differences from the second embodiment. The biggest difference between the electric power source switching apparatus 1C and the electric power source switching apparatus 1A according to the second embodiment is that the electric power source switching apparatus 1C includes a first semiconductor switch 3c and a second semiconductor switch 3d instead of the first semiconductor switch 3a and the second semiconductor switch 3b.

The electric power source switching apparatus 1C includes the first semiconductor switch 3c, the second semiconductor switch 3d and a switch control apparatus 5C. The electric power from the first power supply source 2a is supplied to a plurality of load devices 4a to 4c through the first semiconductor switch 3c. The first semiconductor switch 3c includes a plurality of field-effect transistors M1, M2, which are connected in series such that their body diodes are in the opposite directions.

The electric power from the second power supply source 2b is supplied to a plurality of load devices 4a to 4c through the second semiconductor switch 3d. The second semiconductor switch 3d includes a plurality of field-effect transistors M3, M4, which are connected in series such that their body diodes are in the opposite directions.

The switch control apparatus 5C switches the power supply by outputting control signals (gate voltages) to the field-effect transistors M1, M2 of the first semiconductor switch 3c and to the field-effect transistors M3, M4 of the second semiconductor switch 3d. The switch control apparatus 5C includes the voltage comparator 7, a gate voltage control circuit 6C and the load information 8A.

In accordance with the voltage difference Vd between the output voltages of the first and second power supply sources 2a, 2b, which is detected by the voltage comparator 7, the gate voltage control circuit 6C generates and outputs a gate voltage Vga1 of the field-effect transistor M1 as the first semiconductor switch 3c, and a gate voltage Vga2 of the field-effect transistor M2. In accordance with the voltage difference Vd, the gate voltage control circuit 6C generates and outputs a gate voltage Vgb1 of the field-effect transistor M3 used as the second semiconductor switch 3d, and a gate voltage Vgb2 of the field-effect transistor M4.

Moreover, the gate voltage control circuit 6C is able to generate and output the gate voltages Vga1, Vga2 and the gate voltages Vgb1, Vgb2 in accordance with the load information 8A based on the equivalent electrical resistance and equivalent capacitance of the load devices 4a to 4c in addition to the voltage difference Vd.

In the present embodiment, as depicted in FIG. 8, two field-effect transistors are connected back-to-back in each of the first and second semiconductor switches 3c, 3d. Back-to-back connection is a connection configuration in which the body diodes of two field-effect transistors are connected in series, facing each other. This makes it possible to block a reverse current from the load devices 4 to the first and second power supply sources 2a, 2b, and prevent a through-current flowing in the first and second power supply sources 2a, 2b.

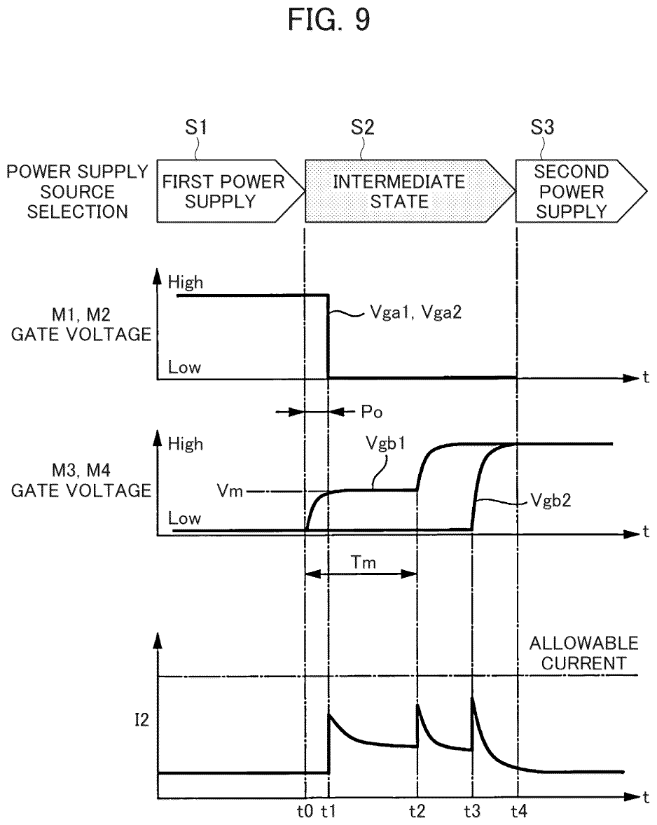

Next, an example of the operation of the electric power source switching apparatus 1C according to the present embodiment will be described with reference to FIG. 9.

FIG. 9 is a diagram that depicts an example of gate voltages Vga1, Vga2, Vgb1, Vgb2, which are generated by the gate voltage control circuit 6C, as an example of the operation of the electric power source switching apparatus 1C. The upper part of FIG. 9 depicts a voltage profile of the gate voltages Vga1, Vga2 at the time of switching from the first power supply source 2a to the second power supply source 2b, the middle part of FIG. 9 depicts a voltage profile of the gate voltages Vgb1 and Vgb2, and the lower part of FIG. 9 depicts a current I2 flowing through the second semiconductor switch 3d.

In FIG. 9, the horizontal axis represents time t.

As is the case with the first embodiment, the following description of the present embodiment assumes that the voltage Va of the first power supply source 2a is 13 V and that the voltage Vb of the second power supply source 2b is 14 V, and relates to an example in which the power supply source is switched from the first power supply source 2a, which generates a low output voltage to the second power supply source 2b, which generates a high output voltage.

As depicted in FIG. 9, when electric power is supplied from the first power supply source 2a to the load devices 4a to 4c (first power supply S1), the gate voltage Vga1 and Vga2 of the first semiconductor switch 3c is a High level, and the gate voltage Vgb1 and Vgb2 of the second semiconductor switch 3d is at a Low level.

When the power supply source is to be switched from the state of the first power supply S1 to the second power supply source 2b, the gate voltage control circuit 6C first sets the gate voltages Vga1, Vga2 of the first semiconductor switch 3c to the Low level.

In the above instance, the gate voltage control circuit 6C raises the gate voltage Vgb1 of the second semiconductor switch 3d to the intermediate voltage Vm immediately before the gate voltages Vga1, Vga2 reach the Low level. As depicted in the middle part of FIG. 9, the present embodiment is configured to provide an overlap period Po in which the gate voltage Vga1 and the gate voltage Vgb1 are simultaneously higher than the Low level. When switching from one power supply source to the other during the overlap period Po, the gate voltage control circuit 6C of the switch control apparatus 5C exercises control such that the field-effect transistor (e.g., field-effect transistor M3) related to the power supply from the other power supply source is placed in the intermediate state before the power supply from the one power supply source is interrupted. The advantageous effect of the overlap period will be described later. The gate voltage control circuit 6C holds the gate voltage Vgb1 at the intermediate voltage Vm for the period of the holding time Tm (intermediate state S2).

Subsequently, the gate voltage control circuit 6C raises the gate voltage Vgb1 from the intermediate voltage Vm to the High level, and then raises the gate voltage Vgb2 from the Low level to the High level. As a result, the power supply source is completely switched from the first power supply source 2a to the second power supply source 2b (second power supply S3).

As is the case with the first embodiment, the holding time Tm is dynamically set in accordance with the voltage difference Vd between the voltages outputted from the first power supply source 2a and the second power supply source 2b. When the voltage difference Vd between the output voltages of the first and second power supply sources 2a, 2b is small, the holding time Tm is shortened, and when the voltage difference Vd is great, the holding time Tm is lengthened. In the present embodiment, a state in which the gate voltage Vgb1 of the second semiconductor switch 3d of the field-effect transistor M3 is between the Low level and the High level is defined as the “intermediate state.”

The current flowing through the second semiconductor switch 3d due to the above-described power supply switching control is depicted as the current I2 in the lower part of FIG. 9. At time to, the gate voltage Vgb1 starts to rise from the Low level. The first peak current flows when the gate voltage Vgb1 rises to the intermediate voltage Vm (time t1), and then, after the first peak current is decreased, the second peak current flows when the gate voltage Vgb1 rises to the High level (time t2). Subsequently, when the gate voltage Vgb2 rises to the High level (time t3), a third peak current flows. When the gate voltages Vgb1, Vgb2 are both at the High level (time t4), the power supply source is completely switched to the second power supply source 2b.

As described above, the switch control apparatus (switch control apparatus 5C) in the fourth embodiment provides the intermediate state in which the field-effect transistor (e.g., field-effect transistor M3) whose body diode is in a direction opposite to the direction of power supply at the time of switching from one power supply source to the other is held in the unsaturated state, and changes the holding time of the intermediate state in accordance with the voltage difference Vd between the voltages outputted from the first and second power supply sources 2a, 2b.

Alternatively, the switch control apparatus (switch control apparatus 5C) in the present embodiment may be configured to provide the intermediate state in which the field-effect transistor (e.g., field-effect transistor M3) whose body diode is in a direction opposite to the direction of power supply at the time of switching from one power supply source to the other is held in the unsaturated state, and change the holding time of the intermediate state in accordance with the information representing the electrical characteristics of the load devices 4a to 4c. Another alternative is to change the holding time Tm of the intermediate state in accordance with the voltage difference Vd and with the information representing the electrical characteristics of the load devices 4a to 4c.

As described above, the present embodiment makes it possible to disperse the peak current in such a manner as to prevent the current I2 (peak current) flowing through the second semiconductor switch 3d from exceeding the allowable current indicated by the dashed line. Further, the present embodiment is configured such that the power supply source can be changed in accordance with the voltage difference Vd between the output voltages of the first power supply source 2a and the second power supply source 2b. Therefore, switching can be performed from one power supply source to another without exceeding the allowable current.

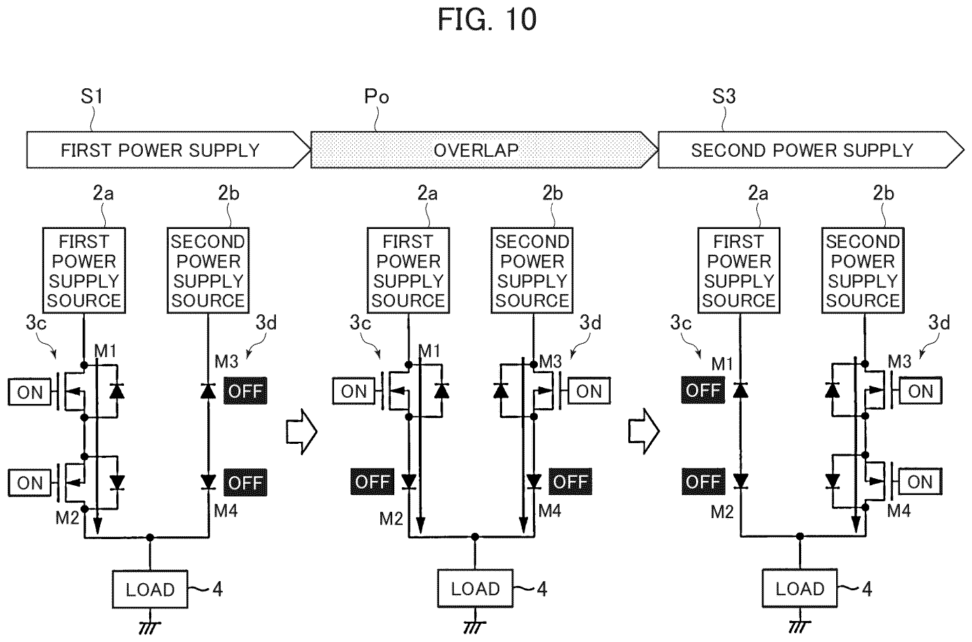

The advantageous effect of providing the overlap period Po for the gate voltages Vga1, Vgb1 of the first and second semiconductor switches 3c, 3d will now be described with reference to FIG. 10.

FIG. 10 is an explanatory diagram illustrating the advantageous effect of providing the overlap period Po for the gate voltage Vga1 of the first semiconductor switch 3c and for the gate voltage Vgb1 of the second semiconductor switch 3d.

The example of FIG. 10 depicts the operations of the field-effect transistors M1 to M4 included in each of the first and second semiconductor switches 3c, 3d at the time of switching from the first power supply source 2a to the second power supply source 2b.

As depicted in FIG. 10, when electric power is being supplied from the first power supply source 2a to the load devices 4a to 4c (first power supply S1), the field-effect transistors M1, M2 of the first semiconductor switch 3c are ON, whereas the field-effect transistors M3, M4 of the second semiconductor switch 3d are OFF. When electric power is being supplied from the second power supply source 2b to the load devices 4a to 4c (second power supply S3), the field-effect transistors M1, M2 of the first semiconductor switch 3c are OFF, whereas the field-effect transistors M3, M4 of the second semiconductor switch 3d are OFF, conversely.

During the overlap period Po, the field-effect transistors M1, M3 are ON, whereas the field-effect transistors M2, M4 are OFF. That is to say, the field-effect transistors M2, M4 are placed in a state where a current flows through each of the body diodes, thereby forming a parallel diode circuit.

Consequently, the present embodiment makes it possible to perform a switching operation without interrupting the power supply. Further, in the present embodiment, any of the body diodes between the first power supply source 2a and the second power supply source 2b is in a reverse-connection configuration. Therefore, the through-current between the first and second power supply sources 2a, 2b can be interrupted.

In the present embodiment, the holding time Tm and the intermediate voltage Vm are set in accordance with the voltage difference Vd between the output voltages of the first and second power supply sources 2a, 2b. However, these parameters can be set in accordance with the voltage difference Vd and the load information 8A, as is the case with the second embodiment. Moreover, the electric power source switching apparatus 1C according to the present embodiment can be combined with the third embodiment in which the information regarding an energized one of the load devices 4 is used.

Although the overlap period Po has been described in conjunction with the present embodiment, the overlap period is not an essential requirement for the present embodiment. However, the configuration of the electric power source switching apparatus 1C in which the overlap period Po is provided for the gate voltages between the first and second semiconductor switches 3c, 3d cannot be applied to the first to third embodiments. The reason is that the first to third embodiments do not have a reverse-connection configuration formed by two field-effect transistors such as the first semiconductor switch 3c and the second semiconductor switch 3d. Therefore, when the overlap period is provided for the gate voltages of the first and second semiconductor switches 3a, 3b in the first to third embodiments, the through-current flows between the first power supply source 2a and the second power supply source 2b.

### Fifth Embodiment

Next, the electric power source switching apparatus according to a fifth embodiment will be described. The fifth embodiment is an example in which the electric power source switching apparatus forming a parallel diode circuit at the time of electric power source switching is configured to suppress an increase in voltage drop and electric power loss due to the forward voltage of a body diode.

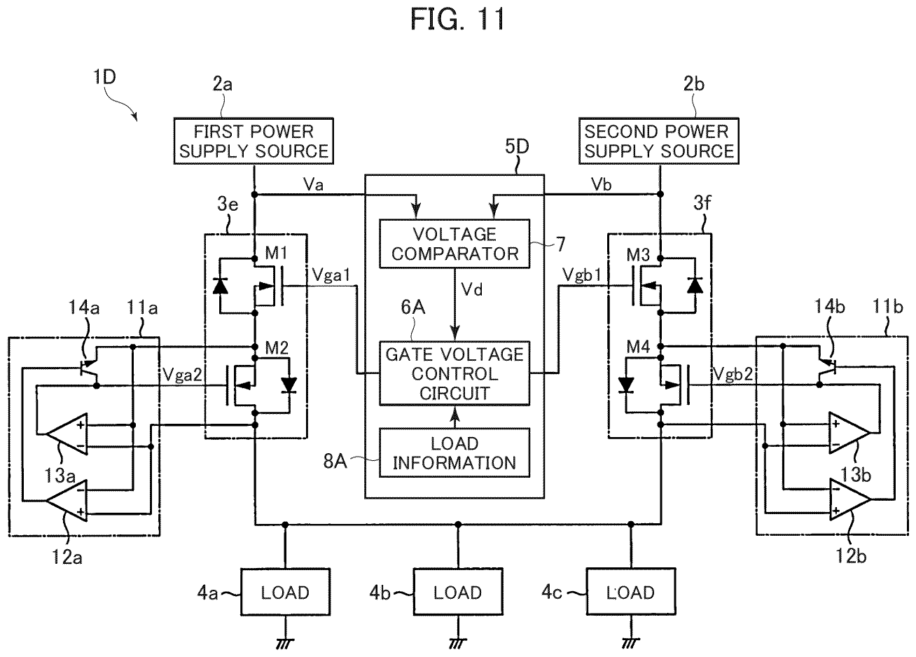

The configuration of the electric power source switching apparatus according to the present embodiment will be described with reference to FIG. 11.

FIG. 11 is a diagram illustrating an example of the configuration of an electric power source switching apparatus 1D according to the present embodiment. The electric power source switching apparatus 1D is basically configured based on the configuration of the electric power source switching apparatus 1C according to the fourth embodiment, and the following description of the electric power source switching apparatus 1D will focus on the differences from the fourth embodiment. The biggest difference between the electric power source switching apparatus 1D and the electric power source switching apparatus 1C according to the fourth embodiment is that the electric power source switching apparatus 1D includes ideal diode control circuits 11a, 11b.

The electric power source switching apparatus 1D includes a first semiconductor switch 3e, a second semiconductor switch 3f and a switch control apparatus 5D. The electric power from the first power supply source 2a is supplied to a plurality of load devices 4a to 4c through the first semiconductor switch 3e. As is the case with the first semiconductor switch 3c in the fourth embodiment, the first semiconductor switch 3e is configured such that the field-effect transistor M1 and the field-effect transistor M2 are connected in reverse. However, the fifth embodiment differs from the fourth embodiment in that the gate voltage of the field-effect transistor M2 is inputted from the ideal diode control circuit 11a.

The electric power from the second power supply source 2b is supplied to a plurality of load devices 4a to 4c through the second semiconductor switch 3f. As is the case with the second semiconductor switch 3d in the fourth embodiment, the second semiconductor switch 3f is configured such that the field-effect transistor M2 and the field-effect transistor M4 are connected in reverse. However, the fifth embodiment differs from the fourth embodiment in that the gate voltage of the field-effect transistor M4 is inputted from the ideal diode control circuit 11b.

The switch control apparatus 5D switches the power supply by outputting control signals (gate voltages) to the field-effect transistor M1 of the first semiconductor switch 3e and to the field-effect transistor M3 of the second semiconductor switch 3f. The switch control apparatus 5D includes the voltage comparator 7, the gate voltage control circuit 6A and the load information 8A. The switch control apparatus 5D may have the same configuration as the switch control apparatus 5A in the second embodiment. Further, the switch control apparatus 5D may have the same configuration as the switch control apparatus 5 in the first embodiment, which does not reference the load information 8.

In accordance with the voltage difference Vd between the output voltages of the first and second power supply sources 2a, 2b, which is detected by the voltage comparator 7, the gate voltage control circuit 6A generates and outputs a gate voltage Vga1 of the field-effect transistor M1, as the first semiconductor switch 3e, and a gate voltage Vgb1 of the field-effect transistor M3 as the second semiconductor switch 3f. Moreover, the gate voltage control circuit 6A is able to generate and output the gate voltage Vga1 of the field-effect transistor M1 and the gate voltage Vgb1 of the field-effect transistor M3 in accordance with the load information 8A based on the equivalent electrical resistance and equivalent capacitance of the load devices 4a to 4c in addition to the voltage difference Vd.

Referring to FIG. 11, in the first semiconductor switch 3e, the gate voltage Vga2 of the field-effect transistor M2 is controlled by the ideal diode control circuit 11a. In the second semiconductor switch 3f, the gate voltage Vgb2 of the field-effect transistor M4 is controlled by the ideal diode control circuit 11b.

The ideal diode control circuit 11a includes operational amplifiers 12a, 13a and a transistor 14a. The operational amplifiers 12a, 13a detect the direction of an electric current in accordance with the drain voltage and source voltage of the field-effect transistor M2. The transistor 14a adjusts the gate voltage Vga2 in accordance with the outputs of the operational amplifiers 12a, 13a.

The power supply to the operational amplifiers 12a, 13a is not depicted. In the example of FIG. 11, a bipolar transistor is used as the transistor 14a. However, the present invention is not limited to the use of a bipolar transistor.

The operational amplifier 12a outputs a High-level signal to the gate of the transistor 14a when the current flowing through the field-effect transistor M2 is in the reverse direction (the reverse direction with respect to the body diode). For example, when the second semiconductor switch 3f is ON and the output voltage of the second power supply source 2b is higher than that of the first power supply source 2a, the current flowing through the field-effect transistor M2 is in the reverse direction. When the current flowing through the field-effect transistor M2 is in the reverse direction, the operational amplifier 12a turns on the transistor 14a, and pulls down the gate voltage Vga2 to immediately cut off the field-effect transistor M2.

The operational amplifier 13a outputs a high-level signal to the gate of the field-effect transistor M2 when the current flowing through the field-effect transistor M2 is in the forward direction (the forward direction with respect to the body diode). The operational amplifier 13a, which operates on a boosted power supply, sets the gate voltage Vga2 at the High level to energize the field-effect transistor M2, and when the current flowing through the field-effect transistor M2 is in the forward direction.

The above-described configuration of the ideal diode control circuit 11a allows a diode operation to be performed with a reduced voltage drop. The ideal diode control circuit 11b has a similar configuration.

The ideal diode control circuit 11b includes operational amplifiers 12b, 13b and a transistor 14b. The operational amplifiers 12b, 13b detect the direction of an electric current in accordance with the drain voltage and source voltage of the field-effect transistor M4. A transistor 14b adjusts the gate voltage Vgb2 in accordance with the outputs of the operational amplifiers 12b, 13b.

The operational amplifier 12b outputs a High-level signal to the gate of the transistor 14b when the current flowing through a field-effect transistor Mf is in the reverse direction (the reverse direction with respect to the body diode). For example, when the first semiconductor switch 3e is ON and the output voltage of the first power supply source 2a is higher than that of the second power supply source 2b, the current flowing through the field-effect transistor M4 is in the reverse direction. When the current flowing through the field-effect transistor M4 is in the reverse direction, the operational amplifier 12b turns on the transistor 14b, and pulls down the gate voltage Vgb2 to immediately cut off the field-effect transistor M4.

The operational amplifier 13b outputs a high-level signal to the gate of the field-effect transistor M4 when the current flowing through the field-effect transistor M4 is in the forward direction (the forward direction with respect to the body diode). The operational amplifier 13b, which operates on a boosted power supply, sets the gate voltage Vgb2 at the High level to energize the field-effect transistor M4, and when the current flowing through the field-effect transistor M4 is in the forward direction.

As described above, regarding a plurality of field-effect transistors included in the semiconductor switch connected to one power supply source and provided with body diodes placed in the forward direction with respect to the direction of power supply (e.g., field-effect transistors M2) and a plurality of field-effect transistors included in the semiconductor switch connected to the other power supply source, the switch control apparatus (switch control apparatus 5D) in the electric power source switching apparatus (electric power source switching apparatus 1D) according to the fifth embodiment cuts off the field-effect transistors (field-effect transistor M2, M4) when the current flowing through the field-effect transistors (e.g., field-effect transistor M2, M4) whose body diodes are in the forward direction with respect to the direction of power supply is in the reverse direction with respect to the direction of output supply.

In the fourth embodiment, which has been described earlier, a parallel diode circuit is formed using the body diodes of the field-effect transistors M2, M4 at the time of electric power source switching. However, such a configuration has a problem in that the forward voltage of the body diodes causes an increase in voltage drop and electric power loss. Meanwhile, the present embodiment is configured to use field-effect transistors having a low ON resistance in order to provide a function equivalent to that of a diode. This makes it possible to prevent damage caused by the through-current flowing between the first and second power supply sources 2a, 2b and reduce voltage drop and electric power loss.

### Sixth Embodiment

Next, the electric power source switching apparatus according to a sixth embodiment will be described. The first and second embodiments have been described with a reference to an example in which, at the time of turn-ON of the first and second semiconductor switches 3a, 3b, the gate voltages Vga, Vgb are controlled by a two-stage voltage profile indicating a period in which the gate voltages Vga, Vgb are held at the intermediate voltage. However, the present invention is not limited to such a configuration. For example, the configuration for turning ON the first semiconductor switch 3 may be as indicated in the following examples of first to third configurations.

### (First Configuration Example for Turning ON Semiconductor Switch)

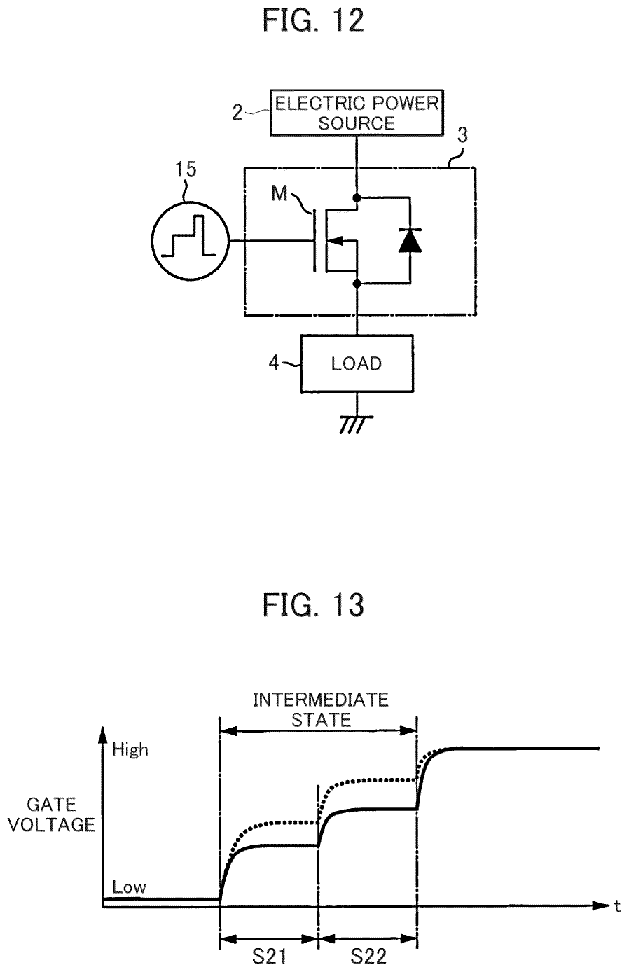

First of all, the first configuration for turning ON the semiconductor switch 3 is described below with reference to FIGS. 12 and 13. The first configuration is an example in which the gate voltage generated by a voltage source is increased in three or more stages in accordance with a voltage profile.

FIG. 12 is a diagram depicting an example of the first configuration for turning ON the semiconductor switch 3 of the electric power source switching apparatus according to the present embodiment. In the first configuration example, electric power is supplied from the power supply source 2 to the load device 4 when the field-effect transistor M of the semiconductor switch 3 is turned on in accordance with the gate voltage generated by a voltage source 15.

FIG. 13 is a diagram illustrating an example of the operation of the semiconductor switch 3 in the first example of the configuration of the electric power source switching apparatus according to the present embodiment. In FIG. 13, the vertical axis represents the gate voltage of the field-effect transistor M, and the horizontal axis represents time t. FIG. 13 depicts an example of the voltage profile indicating that, when the gate voltage rises from the Low level to the High level, the gate voltage rises in three stages, passing through a first intermediate state S21 and a second intermediate state S22. FIG. 13 additionally depicts an example in which the gate voltage (intermediate voltage) is held at a higher value in the first and second intermediate states S21, S22, as indicated by the dashed lines. In addition to the values of the intermediate voltages in the first and second intermediate states S21, S22, the holding time Tm in each of the first and second intermediate states S21, S22 may also be changed appropriately.

### (Second Configuration Example for Turning ON Semiconductor Switch)

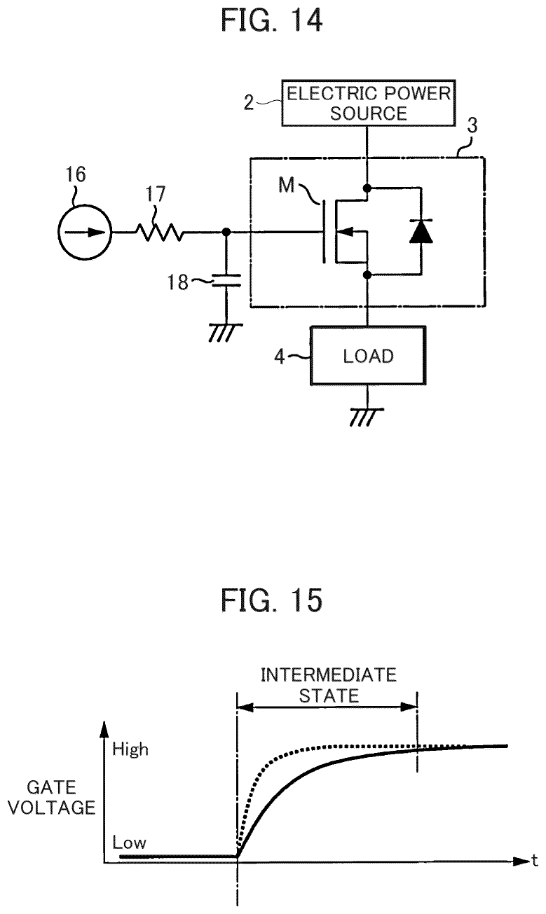

Next, the second configuration for turning ON the semiconductor switch 3 is described below with reference to FIGS. 14 and 15. The second configuration is an example in which the gate voltage is controlled by a current source by utilizing the electrical resistance component and capacitance component of an external circuit connected to the gate of a field-effect transistor.

FIG. 14 is a diagram depicting an example of the second configuration for turning ON the semiconductor switch 3 of the electric power source switching apparatus according to the present embodiment. In the example of the second configuration, a current source 16 is connected to the gate of the field-effect transistor M of the semiconductor switch 3 via an electrical resistor 17. Further, a capacitor 18 is connected at one end to the connection midpoint between the gate of the field-effect transistor M and the electrical resistor 17 and at the other end to ground. The electrical resistor 17 and the capacitor 18 form a so-called CR circuit. The current outputted from the current source 16 passes through the CR circuit, is inputted to the gate, and thus turns on the field-effect transistor M of the semiconductor switch 3. Consequently, electric power is supplied from the power supply source 2 to the load device 4. The above-described CR circuit can be used to adjust the value of the gate voltage in the intermediate state (intermediate voltage) and the holding time Tm.

FIG. 15 is a diagram illustrating an example of the operation of the semiconductor switch 3 in the second example of the configuration of the electric power source switching apparatus according to the present embodiment. As depicted in FIG. 15, the time constant of the CR circuit can be adjusted in order to change the speed at which the gate voltage rises from the Low level to the High level (corresponding to the holding time Tm) can be changed by adjusting For example, the time constant of the CR circuit can be adjusted in order to raise the gate voltage faster, thereby shortening the intermediate state (holding time Tm). Further, when the amount of electric current supplied from the current source 16 is increased, the gate voltage rises to the High level more quickly. That is to say, the amount of electric current supplied from the current source 16 can be adjusted to adjust the holding time Tm during which the gate voltage is within the range of the intermediate voltage (intermediate state). In this case, the gate voltage in the intermediate state is not held at a constant value such as the intermediate voltage Vm described above.

### (Third Configuration Example for Turning ON Semiconductor Switch)

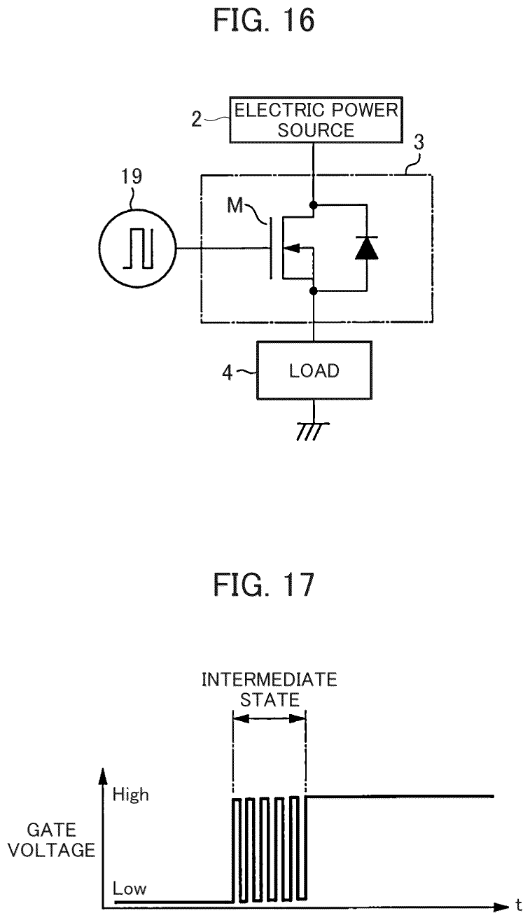

Next, the third configuration for turning ON the semiconductor switch 3 is described below with reference to FIGS. 16 and 17. The third configuration is an example in which a PWM (Pulse Width Modulation) generator is provided to input a PWM waveform to the gate as the intermediate state. In this configuration as well, the intermediate state can be provided in the semiconductor switch so as to obtain the same advantageous effects as those provided by the above-mentioned configuration examples.

FIG. 16 is a diagram depicting an example of the third configuration for turning ON the semiconductor switch 3 of the electric power source switching apparatus according to the present embodiment. The example of the third configuration, which is depicted in FIG. 16, indicates a configuration in which the voltage source 15 in FIG. 12 is replaced by a PWM generator 19. In the example of the third configuration, the field-effect transistor M of the semiconductor switch 3 turns ON in accordance with a PWM signal that is outputted from the PWM generator 19. As a result, electric power is supplied from the power supply source 2 to the load device 4. At this instance, the intermediate state (intermediate voltage) of the gate voltage is generated by controlling the duty ratio of the PWM signal.

FIG. 17 is a diagram illustrating an example of the operation of the semiconductor switch 3 in the third example of the configuration of the electric power source switching apparatus according to the present embodiment. The gate voltage in the intermediate state (corresponding to the intermediate voltage Vm) can be adjusted by controlling the duty ratio of the PWM signal. For example, when the duty ratio of the PWM signal is constant, the gate voltage is held at the intermediate voltage Vm. Further, the time of PWM signal application (the period during which the Low level and the high level are repeated) corresponds to the holding time Tm of the intermediate state.

### [Hardware Configuration of Computer]

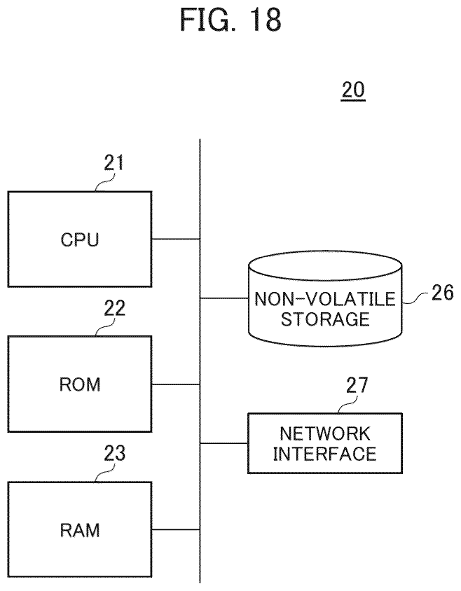

A hardware configuration of a computer included in the electric power source switching apparatus in each of the above-described embodiments will now be described with reference to FIG. 18.

FIG. 18 is a block diagram illustrating an example of the hardware configuration of a computer included in the electric power source switching apparatus according to each embodiment. A calculator 20 depicted in FIG. 18 is hardware used as a so-called computer.

The calculator 20 includes a CPU (Central Processing Unit) 21, a ROM (Read Only Memory) 22, a RAM (Random Access Memory) 23, a non-volatile storage 26, and a network interface 27, all of which are connected to a bus.

The CPU 21 is an example of a processor serving as an arithmetic device. The ROM 22 and RAM 23 are examples of the memories. For example, the load information 8A is stored in the ROM 22 or the non-volatile storage 26.

The non-volatile storage 26 is a non-volatile storage element having a larger capacity than the memories. A program for implementing the functions of the electric power source switching apparatus in each of the above-described embodiments is stored in the non-volatile storage 26. The non-volatile storage 26 is an example of a computer-readable non-transitory recording medium. The program may be stored in the ROM 22.

The network interface 27 includes, for example, a communication device that controls communication with other devices (e.g., ECU) via a network such as a communication line or a CAN. The network interface 27 is an example of an input/output device.

Although an example of the hardware configuration of the computer included in the electric power source switching apparatus has been described with reference to FIG. 18, the hardware configuration of a computer included in the controller 111 may be similar to the above-described hardware configuration.

Further, the present invention is not limited to the above-described embodiments. It is obvious that the present invention may be used in various other applications and susceptible to various other modifications without departing from the spirit of the present invention that is described in the appended claims. For example, the above-described embodiments have been described in detail in order to facilitate the understanding of the present invention, and the present invention is not necessarily limited to those including all of the described configurations. Furthermore, some of the above-mentioned component elements in one embodiment may be replaced with the component elements in another embodiment. Moreover, the component elements in one embodiment may be added to the component elements in another embodiment. In addition, part of the configuration of each of the embodiments can be subjected to addition or replacement, and deletion with respect to other configurations.

Further, for example, the above-mentioned component elements, functions, and processing sections may be partly or wholly implemented by hardware, that is, for example, by designing integrated circuits. Processor devices in a broad sense, such as an FPGA (Field Programmable Gate Array) or an ASIC (Application Specific Integrated Circuit) may be used as the hardware.

Furthermore, control lines and information lines considered necessary for explanation are indicated in conjunction with the above-described embodiments. Not all the control lines and information lines relevant to products are indicated. Actually, almost all component elements may be considered interconnected.

### LIST OF REFERENCE SIGNS

1, 1A to 1D: electric power source switching apparatus, 2a: first power supply source, 2b: second power supply source, 3: semiconductor switch, 3a, 3c, 3e: first semiconductor switch, 3b, 3b, 3f: second semiconductor switch, 4, 4a to 4c: load device, 5, 5A to 5D: switch control apparatus, 6, 6A, 6C: gate voltage control circuit, 7: voltage comparator, 8A: load information, 9a to 9c: load switch, 10: load switch control apparatus, 11a, 11b: ideal diode control circuit, 12a, 12b, 13a, 13b: operational amplifier, 14a, 14b: transistor, 15: voltage source, 16: current source, 19: PWM generator, 100: vehicle, 110: vehicle control apparatus, 120: sensors, 130: actuators

1. An electric power source switching apparatus comprising:
a first semiconductor switch that is disposed between a load device and a first power supply source configured to supply electric power to the load device;
a second semiconductor switch that is disposed between the load device and a second power supply source configured to supply electric power to the load device; and
a switch control apparatus that controls drive voltages of the first and second semiconductor switches;
wherein, when switching from one of the first and second power supply sources to the other, the switch control apparatus provides an intermediate state in which the semiconductor switch connected to the power supply source configured to supply electric power after switching is held in an unsaturated state, and changes a holding time of the intermediate state in accordance with a voltage difference between the voltages outputted from the first and second power supply sources.

2. The electric power source switching apparatus according to claim 1,
wherein the switch control apparatus changes the holding time to be longer than a reference time when the voltage difference is greater than a predetermined value, and changes the holding time to be shorter than the reference time when the voltage difference is equal to or smaller than the predetermined value.

3. The electric power source switching apparatus according to claim 2,
wherein the switch control apparatus changes the holding time of the intermediate state in accordance with the voltage difference and with information representing electrical characteristics of the load device.

4. The electric power source switching apparatus according to claim 3,
wherein an output terminal of the first semiconductor switch and an output terminal of the second semiconductor switch are electrically connected, and a plurality of the load devices are connected to the output terminals.

5. The electric power source switching apparatus according to claim 4,
wherein the switch control apparatus changes the holding time of the intermediate state in accordance with the information representing the electrical characteristics of an energized one of the plurality of the load devices.

6. The electric power source switching apparatus according to claim 5,
wherein, before switching from one power supply source to the other, the switch control apparatus stops the power supply to one of the plurality of the load devices, and;
wherein the switch control apparatus changes the holding time of the intermediate state in accordance with the information representing the electrical characteristics of an energized one of the plurality of the load devices.

7. The electric power source switching apparatus according to claim 1,
wherein the first and second semiconductor switches are configured such that a plurality of field-effect transistors are connected in series so as to position body diodes in opposite directions; and
wherein, when switching from one power supply source to the other, the switch control apparatus provides an intermediate state in which the field-effect transistor whose body diode is in a direction opposite to a direction of power supply is held in the unsaturated state, and changes the holding time of the intermediate state in accordance with the voltage difference between the voltages outputted from the first and second power supply sources.

8. The electric power source switching apparatus according to claim 7,
wherein, when switching from one power supply source to the other, the switch control apparatus provides an intermediate state in which the field-effect transistor whose body diode is in a direction opposite to the direction of power supply is held in the unsaturated state, and changes the holding time of the intermediate state in accordance with the information representing electrical characteristics of the load device.

9. The electric power source switching apparatus according to claim 7,
wherein, when switching from one power supply source to the other, the switch control apparatus exercises control such that the other field-effect transistor related to the power supply from the other power supply source is placed in the intermediate state before the power supply from the one power supply source is interrupted.

10. The electric power source switching apparatus according to claim 7,
wherein, regarding a plurality of field-effect transistors included in the semiconductor switch connected to one power supply source and provided with body diodes placed in a forward direction with respect to the direction of power supply and a plurality of field-effect transistors included in the semiconductor switch connected to the other power supply source, the switch control apparatus cuts off the field-effect transistors when the current flowing through the field-effect transistors whose body diodes are in the forward direction with respect to the direction of power supply is in a reverse direction with respect to the direction of output supply.

11. The electric power source switching apparatus according to claim 3,
wherein the information representing the electrical characteristics of the load device includes at least an equivalent electrical resistance and an equivalent capacitance

12. A vehicle control apparatus comprising:
a controller that controls a vehicle; and
an electric power source switching apparatus,
wherein the electric power source switching apparatus includes a first semiconductor switch, a second semiconductor switch, and a switch control apparatus, the first semiconductor switch being disposed between a load device disposed in the vehicle and a first power supply source configured to supply electric power to the load device, the second semiconductor switch being disposed between the load device and a second power supply source configured to supply electric power to the load device, the switch control apparatus controlling drive voltages of the first and second semiconductor switches; and
wherein, when switching from one of the first and second power supply sources to the other, the switch control apparatus provides an intermediate state in which the semiconductor switch connected to the power supply source configured to supply electric power after switching is held in an unsaturated state, and changes a holding time of the intermediate state in accordance with a voltage difference between the voltages outputted from the first and second power supply sources.

13. An electric power source switching method adopted by an electric power source switching apparatus including a first semiconductor switch, a second semiconductor switch, and a switch control apparatus, the first semiconductor switch being disposed between a load device and a first power supply source configured to supply electric power to the load device, the second semiconductor switch being disposed between the load device and a second power supply source configured to supply electric power to the load device, the switch control apparatus controlling drive voltages of the first and second semiconductor switches, the electric power source switching method comprising the steps of:
at the time of switching from one of the first and second power supply sources to the other, causing the switch control apparatus to provide an intermediate state in which the semiconductor switch connected to the power supply source configured to supply electric power after switching is held in an unsaturated state, and detects the voltage difference between the voltages outputted from the first and second power supply sources; and
changing a holding time of the intermediate state in accordance with the voltage difference.
